(19) United States
(12) Patent Application Publication
(10) Pub. No.: US 2001/0038150 A1
(43) Pub. Date: Nov. 8, 2001

(54) Semiconductor device manufactured by package group molding and dicing method

(75) Inventor: Yasuhiro Suzuki, Tokyo (JP)

Correspondence Address: HELFGOTT & KARAS, P.C., 60th FLOOR, EMPIRE STATE BUILDING, NEW YORK, NY, 10118, US

(73) Assignee: NEC CORPORATION

(21) Appl. No.: 09/726,980

(22) Filed: Nov. 30, 2000

(30) Foreign Application Priority Data
Nov. 30, 1999 (JP) 11-341340

(51) Int. Cl. H01L 23/48; H01L 23/52; H01L 29/40; H01L 21/44; H01L 21/48; H01L 21/50

(52) U.S. Cl. 257/778; 257/780; 438/110; 438/113; 438/127

(57) ABSTRACT

A semiconductor device manufactured by a package group molding and dicing method. The semiconductor device comprises: a wiring substrate portion having wiring conductors formed on at least a first surface thereof and having a solder resist layer which is formed on the first surface of the wiring substrate portion except on the peripheral portion on the first surface of the wiring substrate portion and which has opening portions for forming external terminals; and at least one semiconductor chips bonded on a second surface of the wiring substrate portion, the second surface being an opposite surface to the first surface. The semiconductor device further comprises a mold resin portion for sealing the at least one semiconductor chips on the wiring substrate portion.

### FIELD OF THE INVENTION

The present invention relates generally to a semiconductor device, a wiring substrate used for manufacturing a semiconductor device, and a method of manufacturing a semiconductor device. More particularly, the present invention relates to manufacturing a semiconductor device by a package group molding and dicing method.

The package group molding and dicing method is a method in which a plurality of semiconductor chips are bonded or mounted onto a single wiring substrate, the semiconductor chips are resin molded or sealed as a group or groups, and then the wiring substrate with semiconductor chips are diced into separate semiconductor devices.

### BACKGROUND OF THE INVENTION

First, an explanation will be made below on a conventional technology using the package group molding and dicing method. This explanation will be made with reference to a Ball Grid Array (BGA) type semiconductor device in which a semiconductor chip is coupled within the semiconductor device by using wire bonding technology and is coupled with outside by using metal balls.

FIG. 3A is a partial plan view showing the backside surface of a conventional wiring substrate used for manufacturing a semiconductor device. FIG. 3B is a partial cross sectional view taken along line C-C of FIG. 3A and showing a part of the wiring substrate of FIG. 3A in detail. FIG. 4A is a plan view showing the backside of a conventional single semiconductor device manufactured by using the wiring substrate shown in FIGS. 3A and 3B. FIG. 4B is a partial cross sectional view taken along line D-D of FIG. 4A and showing a part of the semiconductor device of FIG. 4A in detail.

As shown in FIGS. 3A and 3B, the conventional wiring substrate 130 comprises a base material portion or base board 101, copper wiring conductors 103 and a solder resist layer or portion 104. In the base board 101, there are provided through holes 102, and face surface side and the back surface side of the base board 101 communicate with each other via the through holes 102. On the face side surface and the backside surface of the base board 101 and on the inner surface of the through holes 102, there are formed copper wiring conductors 103. Wire bonding portions 111 of the copper wiring conductors 103 on the face surface of the base board 101 and land portions 112 of the copper wiring conductors 103 on the back surface of the base board 101 are electrically coupled with each other. On the land portions 112, external terminals are bonded afterwards. The face surface of the base board 101 is wholly covered by the solder resist layer 104 except the wire bonding portions 111. Also, the solder resist layer 104 fills the through holes 102. The back surface of the base board 101 is wholly covered by the solder resist layer 104 except the land portions 112 for bonding the external terminals. Therefore, the land portions 112 for bonding external terminals on the back side surface of the wiring substrate 130 are exposed via openings 104a of the solder resist layer 104. Also, the wire bonding portions 111 on the face surface side of the wiring substrate 130 are exposed via opening portions 104b of the solder resist layer 104. In this way, base board 101 and the copper wiring conductors 103 are coated with the solder resist layer 104.

In FIG. 3A, for the sake of easy understanding, outer edge locations of semiconductor device packages obtained by dicing the wiring substrate 130 as mentioned later are shown by dotted lines 110. The wiring substrate 130 comprises a plurality of wiring substrate portions or modules 130a which are disposed in a matrix and each of which corresponds to a single semiconductor device surrounded by the dotted lines 110 showing the outer edges of the semiconductor device packages after dicing. A solder resist layer 104 is formed on whole area of the backside surface of the wiring substrate 130 except solder resist opening portions 104a. Therefore, the solder resist layer 104 is formed also on the dotted lines 110 corresponding to the outer circumference of each of the diced semiconductor device packages and on both sides of the dotted lines 110.

Next, an explanation will be made on a conventional method of manufacturing a semiconductor device which uses a package group molding and dicing system and which uses the above-mentioned wiring substrate 130.

First, the wiring substrate 130 having the above-mentioned structure is prepared, and a plurality of semiconductor device chips 107 are bonded on the surface of the wiring substrate 130 using adhesive material, that is, die bonding material, 106. Then, by using gold wires 108, electrode pads of the semiconductor device chips 107 and wire bonding portions 111 of the wiring substrate 130 are wire bonded to electrically couple therebetween.

Then, a process of package group molding is performed. That is, the plurality of semiconductor chips bonded on the wiring substrate 130 and the gold bonding wires are molded or sealed within mold resin as a whole. When performing such resin molding, a metallic mold having a predetermined shape is disposed on the surface of the wiring substrate 130, and the space formed by the metallic mold and the wiring substrate 130 is filled with the mold resin. To perform the package group molding, the mold resin is filled continuously on the wiring substrate 130 including portions between the adjacent semiconductor chips.

Solder balls 105 for constituting external terminals are then bonded to the land portions 112 for providing external terminals, which land portions are exposed via opening portions 104a of the solder resist layer 104. Thereby, a substrate assembly is obtained.

A dicing process is then performed to obtain separate semiconductor devices. As an example, an explanation will be made on the case the substrate assembly is diced by using a dicing saw. The dicing saw, that is, a cutting blade, is made, for example, by adhering diamond abrasive onto the outer circumference of a metal disk. The cutting blade is rotated, and, by using the rotating cutting blade, the substrate assembly is cut along the cutting lines of the wiring substrate 130. That is, the substrate assembly is cut along a grid shaped cutting area 114 located between the wiring substrate portions 130a shown by dotted lines 110 in FIG. 3A. In this case, the solder resist layer 104, the base board 101 and the mold resin 109 are cut by the cutting blade. Thereby, the substrate assembly is cut into separate pieces, and, as a result, separate semiconductor devices 131 as shown in FIGS. 4A and 4B are manufactured.

In the semiconductor devices 131 manufactured in this way according to the package group molding and dicing method, the side surface portions are formed by cutting the substrate assembly in the above-mentioned package dicing process. That is, each of the side surfaces of the semiconductor devices 131 is formed as a single flat plane which is a cut plane obtained by the package dicing. As shown in FIG. 4B, the outer edge portion of the wiring substrate 130 formed of the base board 101, the copper wiring conductors 103 and the solder resist layer 104, and the edge portion of the mold resin 109 are located coplanar with each other in the side surface of the semiconductor device 131 which is the cut plane formed by the package dicing. It should be noted that the outer edge portion of the solder resist layer 104, together with the outer edge portion of the wiring substrate 130, is also located at the side surface of the semiconductor device 131 which is the cut plane formed by the package dicing.

The solder resist 104 functions to electrically isolate between wiring conductors, between external terminals, between the wiring conductors and the semiconductor chip, and the like.

On the backside surface of the above-mentioned conventional wiring substrate 130, there exists the solder resist layer 104 even in an area of the wiring substrate 130 including the portion of the dicing lines and both side portions of the dicing lines, that is, in an area with which the dicing blade comes into contact. Therefore, when the substrate assembly is diced, the dicing blade and the solder resist come into contact with each other, and the solder resist is cut by the dicing blade. As a result, a stress or load due to the dicing is directly applied to the solder resist 104 in the vicinity of the peripheral portion of the semiconductor device 131. Thereby, defects 140 such as cracks, chips and the like may occur in the solder resist 104 of the manufactured semiconductor device 131.

Also, there is a possibility that the cracks are formed not only in the solder resist layer 104, but also in the copper wiring conductors 103 under the solder resist layer 104. In such case, the copper wiring conductors 103 may be broken. Also, when a part of the solder resist layer 104 chips, there is a possibility that a part of the copper wire conductors 103 is exposed. In such case, since a portion of the solder resist layer 104 insulating between the copper wiring conductors 103 is lost, there is a high possibility that the copper wiring layers 103 are short-circuited. Therefore, a manufacturing yield of the semiconductor devices is deteriorated, and a manufacturing cost thereof becomes relatively high.

The conventional semiconductor devices mentioned above are disclosed in Japanese patent laid-open publication No. 8-274211 and Japanese patent No. 2606603. In such conventional semiconductor devices, however, since the solder resist layers are disposed until the peripheral portions on the backside of the semiconductor device packages, it is impossible to avoid the above-mentioned problems occurring when the substrate assembly is diced into separate semiconductor devices.

### SUMMARY OF THE INVENTION

Therefore, it is an object of the present invention to obviate the disadvantages of the conventional semiconductor device, the conventional wiring substrate and the conventional method of manufacturing the semiconductor device.

It is another object of the present invention to provide a semiconductor device, a wiring substrate and a method of manufacturing a semiconductor device in which dicing blade and solder resist layer do not come into contact with each other and defects such as cracks, chips and the like do not occur in the solder resist.

It is still another object of the present invention to provide a semiconductor device, a wiring substrate and a method of manufacturing a semiconductor device in which break and short circuit of wiring conductors can be effectively avoided.

It is still another object of the present invention to provide a semiconductor device, a wiring substrate and a method of manufacturing a semiconductor device in which a manufacturing yield of a semiconductor device can be improved and a manufacturing cost thereof can be lowered.

According to a first aspect of the present invention, there is provided a semiconductor device comprising: a wiring substrate portion having wiring conductors formed on at least a first surface thereof and having a solder resist layer which is formed on said first surface of said wiring substrate portion except on the peripheral portion on said first surface of the wiring substrate portion and which has opening portions for forming external terminals; and at least one semiconductor chips bonded on a second surface of said wiring substrate portion, said second surface being an opposite surface to said first surface.

When a semiconductor device having this structure is manufactured, a cutting tool such as a cutting blade and the like does not contact with a solder resist layer on the backside surface of a wiring substrate in a dicing process during a manufacturing process. Therefore, it is possible to avoid occurrence of defects such as cracks, chips and the like in the solder resist layer and to safely perform package dicing. Thus, it is possible to avoid occurrence of breaks and short circuits of wiring conductors caused by the defects of the solder resist layer. Also, it is possible to improve a manufacturing yield of the semiconductor device and to reduce a manufacturing cost thereof.

In this case, it is preferable that the semiconductor device further comprises a mold resin portion for sealing the at least one semiconductor chips on the wiring substrate portion.

It is also preferable that, in the peripheral portion on the first surface of the wiring substrate portion, an insulating base material layer of the wiring substrate portion is exposed.

It is further preferable that, on the first surface of the wiring substrate, the wiring conductors are covered with the solder resist layer except portions which are exposed via the opening portions for forming external terminals.

It is advantageous that the semiconductor chip is electrically coupled with wiring conductors formed on the second surface of the wiring substrate.

It is also advantageous that the semiconductor device further comprises the external terminals formed on portions of the first surface of the wiring substrate which are exposed via the opening portions for forming external terminals.

It is further advantageous that a solder resist layer is also formed on the second surface of the wiring substrate portion.

It is preferable that the solder resist layer is not formed on a peripheral portion on the second surface of the wiring substrate.

It is also preferable that the semiconductor device is manufactured by using a package group molding and dicing method.

According to a second aspect of the present invention, there is provided a wiring substrate used for manufacturing a semiconductor device, the wiring substrate comprising: wiring conductors formed on at least a first surface of the wiring substrate; a plurality of wiring substrate portions which are located regularly and each of which corresponds to a single semiconductor device to be manufactured; and a plurality of solder resist layer portions which are formed on the first surface of respective wiring substrate portions and each of which has opening portions for forming external terminals, an outer circumference of each of the solder resist layer portions being located inside a corresponding one of the wiring substrate portions.

When a wiring substrate having such structure is used for manufacturing a semiconductor device by the package group molding and dicing method, a cutting tool such as a cutting blade and the like does not contact with a solder resist layer on the backside surface of the wiring substrate in a dicing process during a manufacturing process. Therefore, it is possible to avoid occurrence of defects such as cracks, chips and the like in the solder resist layer and to safely perform package dicing. Thus, it is possible to avoid occurrence of breaks and short circuits of wiring conductors caused by the defects of the solder resist layer. Also, it is possible to improve a manufacturing yield of the semiconductor device and to reduce a manufacturing cost thereof.

In this case, it is preferable that, in a peripheral portion of each of the wiring substrate portions and an area between the wiring substrate portions on the first surface of the wiring substrate, the resist layer is not formed and an insulating base material layer of the wiring substrate is exposed.

It is also preferable that, on the first surface of the wiring substrate, the wiring conductors are covered with the solder resist layer except portions which are exposed via the opening portions for forming external terminals.

It is further preferable that the wiring substrate is used for manufacturing the semiconductor device by using a package group molding and dicing method.

It is advantageous that the semiconductor device is manufactured by mounting at least one semiconductor chips on a second surface of each of the wiring substrate portions opposite to the first surface and by dicing the wiring substrate into the wiring substrate portions.

According to a third aspect of the present invention, there is provided a method of manufacturing a semiconductor device comprising: preparing a wiring substrate having wiring conductors formed on at least a first surface of the wiring substrate, the wiring substrate having: a plurality of wiring substrate portions which are located regularly and each of which corresponds to a single semiconductor device to be manufactured; and a plurality of solder resist layer portions which are formed on the first surface of respective wiring substrate portions and each of which has opening portions for forming external terminals, an outer circumference of each of the solder resist layer portions being located inside a corresponding one of the wiring substrate portions; mounting at least one semiconductor chips on a second surface of each of the wiring substrate portions opposite to the first surface; and dicing the wiring substrate into the semiconductor devices each comprising a wiring substrate portion, the wiring substrate being cut by a cutting tool along an outer circumference of the wiring substrate portion, and the cutting tool does not contact the solder resist layer portions on the first surface of the wiring substrate.

By this method, when a wiring substrate is diced into separate semiconductor devices, a cutting tool such as a cutting blade and the like does not contact with a solder resist layer on the backside surface of the wiring substrate. Therefore, it is possible to avoid occurrence of defects such as cracks, chips and the like in the solder resist layer and to safely perform package dicing. Thus, it is possible to avoid occurrence of breaks and short circuits of wiring conductors caused by the defects of the solder resist layer. Also, it is possible to improve a manufacturing yield of the semiconductor device and to reduce a manufacturing cost thereof.

In this case, it is preferable that, in a peripheral portion of each of the wiring substrate portions and an area between the wiring substrate portions on the first surface of the wiring substrate, the resist layer is not formed and an insulator base board layer of the wiring substrate is exposed.

It is also preferable that, on the first surface of the wiring substrate, the wiring conductors are covered with the solder resist layer except portions which are exposed via the opening portions for forming external terminals.

It is further preferable that the method of manufacturing a semiconductor device further comprises: after mounting at least one semiconductor chips on the second surface of each of the wiring substrate portions, sealing the semiconductor chips mounted on the second surface of the wiring substrate by using mold resin; and wherein, in the dicing the wiring substrate into the semiconductor devices, the cutting tool cuts the wiring substrate and the mold resin on the second surface of the wiring substrate along the outer circumference of the wiring substrate portions without contacting the solder resist layer on the first surface of the wiring substrate.

It is advantageous that, in the mounting at least one semiconductor chips on the second surface of each of the wiring substrate portions, the at least one semiconductor chips are electrically coupled with wiring conductors formed on the second surface of corresponding one of the wiring substrate portions.

It is also advantageous that the preparing the wiring substrate comprises: preparing a base material layer made of an insulating material; forming wiring conductors in predetermined areas on at least a first surface of the base material layer, and forming a plurality of wiring substrate portions which are located regularly and each of which corresponds to a single semiconductor device to be manufactured; and forming a plurality of solder resist layer portions which are formed on the first surface of respective wiring substrate portions and each of which has opening portions for forming external terminals, an outer circumference of each of the solder resist layer portions being located inside a corresponding one of the wiring substrate portions and, on the first surface of the wiring substrate, the wiring conductors are covered with the solder resist layer except portions which are exposed via the opening portions for forming external terminals.

### BRIEF DESCRIPTION OF THE DRAWINGS

These and other features, and advantages, of the present invention will be more clearly understood from the following detailed description taken in conjunction with the accompanying drawings, in which like reference numerals designate identical or corresponding parts throughout the figures, and in which:

FIG. 1A is a partial plan view showing a backside surface of a wiring substrate used for manufacturing a semiconductor device according to an embodiment of the present invention;

FIG. 1B is a partial cross sectional view taken along line A-A of FIG. 1A and showing a part of the wiring substrate of FIG. 1A in detail;

FIG. 2A is a plan view showing a backside surface of a semiconductor device according to an embodiment of the present invention;

FIG. 2B is a partial cross sectional view taken along line B-B of FIG. 2A and showing a part of the semiconductor device of FIG. 2A in detail;

FIG. 3A is a partial plan view showing a backside surface of a conventional wiring substrate used for manufacturing a semiconductor device;

FIG. 3B is a partial cross sectional view taken along line C-C of FIG. 3A and showing a part of the wiring substrate of FIG. 3A in detail;

FIG. 4A is a plan view showing a backside surface of a conventional semiconductor device; and

FIG. 4B is a partial cross sectional view taken along line D-D of FIG. 4A and showing a part of the semiconductor device of FIG. 4A in detail.

### DESCRIPTION OF A PREFERRED EMBODIMENT

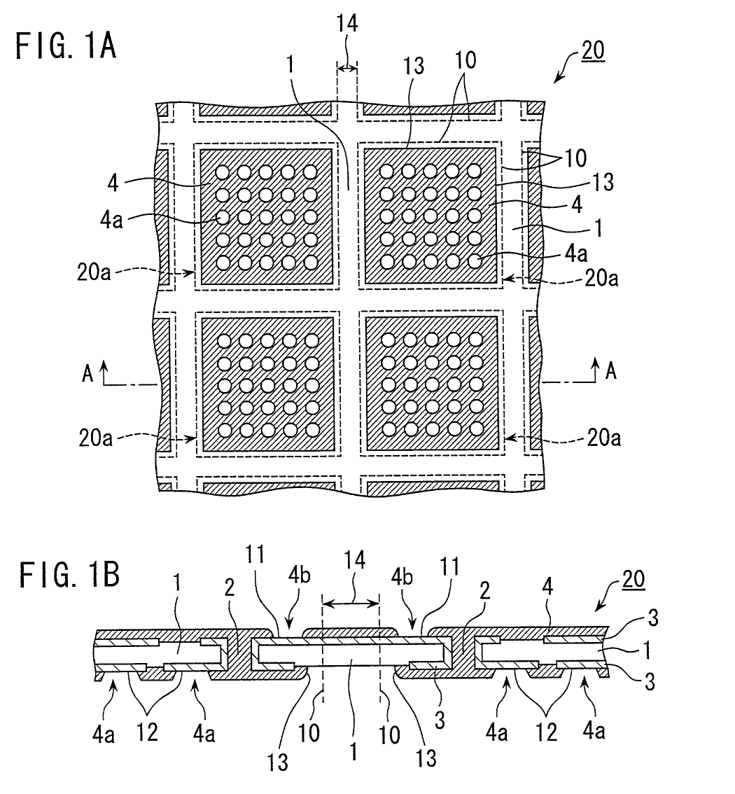

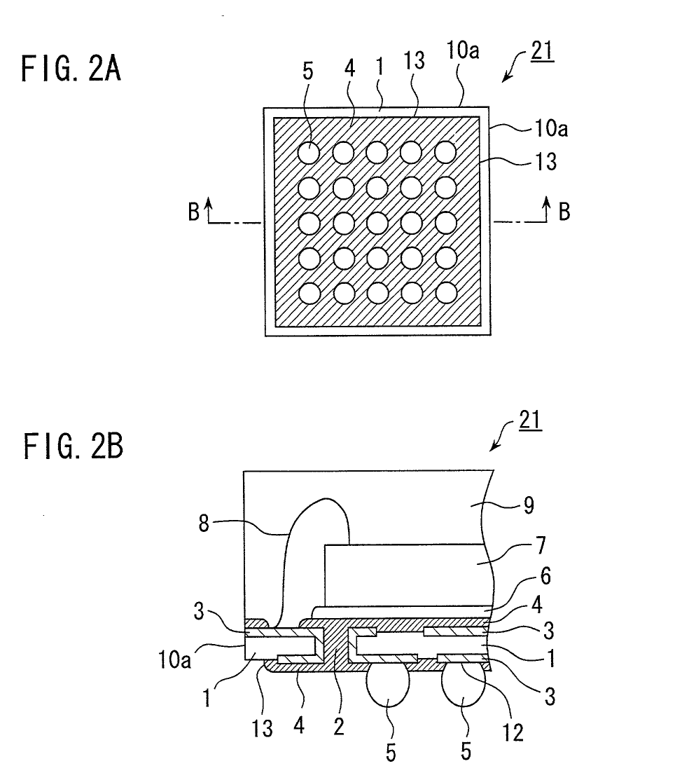

With reference to the drawing, an explanation will be made on a semiconductor device, a wiring substrate and a method of manufacturing the semiconductor device according to an embodiment of the present invention. FIG. 1A is a partial plan view showing the backside surface of a wiring substrate used for manufacturing a semiconductor device according to an embodiment of the present invention. FIG. 1B is a partial cross sectional view taken along line A-A of FIG. 1A and showing a part of the wiring substrate of FIG. 1A in detail. FIG. 2A is a plan view showing the backside surface of a single semiconductor device fabricated by using the wiring substrate shown in FIGS. 1A and 1B. FIG. 2B is a partial cross sectional view taken along line B-B of FIG. 2A and showing a part of the semiconductor device of FIG. 2A in detail.

As shown in FIGS. 1A and 1B, the wiring substrate 20 according to an embodiment of the present invention comprises a base board 1, copper wiring conductors 3 and a solder resist layer 4. Through holes 2 are provided in the base board 1, and the face side and the back side of the base board 1 communicate with each other via the through holes 2. On the face side surface and the backside surface of the base board 1, there are formed the copper wiring conductors 3. Also, on the inner surface of the through holes 2, there are formed the copper wiring conductors 3, so that wire bonding portions 11 of the copper wiring conductors 3 on the face side surface of the base board 1 and land portions 12 of the copper wiring conductors 3 for bonding external terminals on the back surface of the base board 1 are electrically coupled with each other. The face side surface of the base board 1 is coated with the solder resist layer 4 except at least the wire bonding portions 11. Also, the through holes 2 are filled with the solder resist material of the solder resist layer 4. On the other hand, the back side surface of the base board 1 is coated with the solder resist layer 4 except at least the land portions 12 for bonding external terminals and except areas in the proximity of portions which are cut in the package dicing process mentioned later. Therefore, the land portions 12 for bonding external terminals on the back side surface of the wiring substrate 20 are exposed via opening portions 4a of the solder resist layer 4. Also, the wire bonding portions 11 on the face side surface of the wiring substrate 20 are exposed via opening portions 4b of the solder resist layer 4. In this way, the base board 1 and the copper wiring layer 3 are coated by the solder resist layer 4.

For the sake of easy understanding, in FIG. 1A, outer edge locations of semiconductor device packages obtained by dicing the wiring substrate 20 as mentioned later are shown by dotted lines 10. The wiring substrate 20 comprises a plurality of wiring substrate portions or modules 20a which are disposed in a matrix and each of which corresponds to a single semiconductor device surrounded by the dotted lines 10 showing the outer edges of the semiconductor device package after dicing.

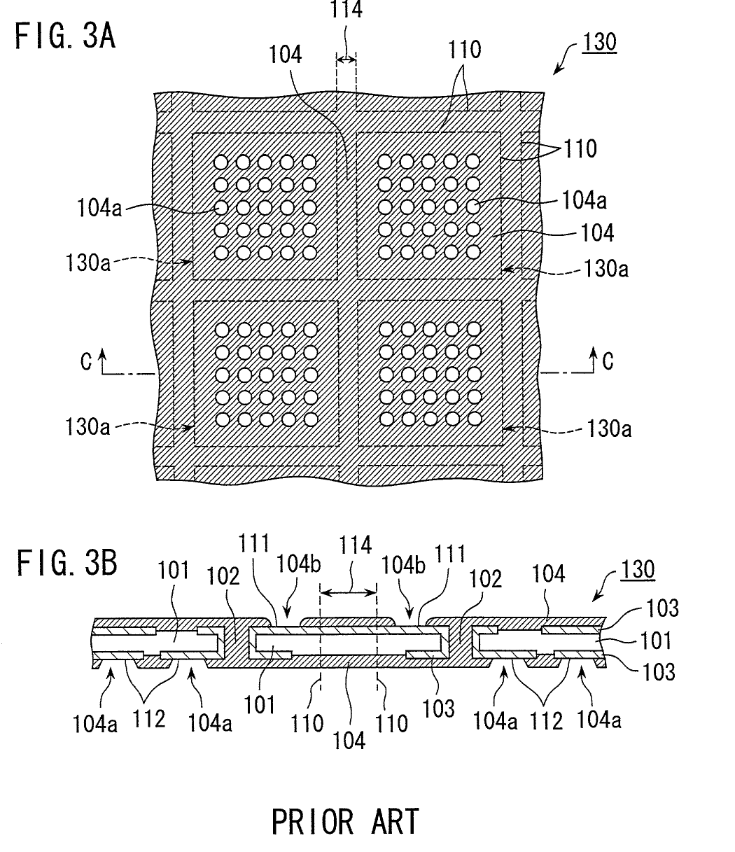

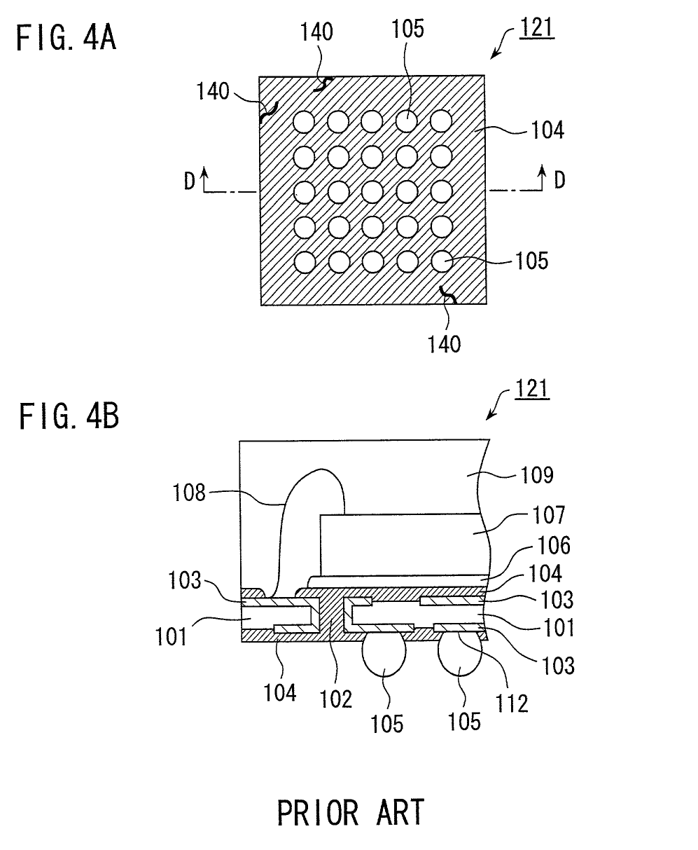

The wiring substrate 20 according to this embodiment has substantially the same structure as that of the conventional wiring substrate 130 shown in FIGS. 3A and 3B, except the arrangement of the areas where the solder resist layer 4 is formed on the back side of the wiring substrate 20. In the wiring substrate 20 according to this embodiment, the solder resist layer 4 is not formed on the location corresponding to the circumference portion of each semiconductor device package after dicing and on the area on both sides of the location. That is, the outer circumference 13 of each area of the solder resist layer 4 on the back side of the wiring substrate 20 is located slightly inside the location 10 corresponding to the outer circumference of each of the packages after dicing. On the area between the outer circumference 13 of the solder resist layer 4 and the location 10 corresponding to the outer circumference of each of the packages after dicing, and on the area 14 outside the location 10 corresponding to the outer circumference of each of the packages after dicing, that is, the area 14 to be cut, the solder resist layer 4 is not applied and the base board 1 is exposed in these area. Therefore, each of the wiring substrate portions 20a has a peripheral portion on the backside of the wiring substrate portion 20a where the solder resist is not applied and where the base board 1 is exposed.

The base board 1 can be made by using an insulator glass epoxy substrate, a tape type material such as a polyimide tape and the like, and so on. However, the material of the base board 1 is not limited to these materials. The glass epoxy substrate can be fabricated, for example, by impregnating a glass cloth with epoxy resin.

As mentioned above, the wiring substrate 20 comprises a plurality of wiring substrate portions or modules 20a disposed in a matrix, and each of the wiring substrate portions 20a corresponds to a single semiconductor device and is surrounded by the dotted line 10 showing the outer edges of the semiconductor device package after dicing. However, the wiring substrate portions 20a can be disposed regularly in an arrangement other than a matrix arrangement. For example, it is possible to dispose the wiring substrate portions 20a in a linear arrangement.

Also, in the above, the base board 1 is shown as a single layer substrate. However, it is also possible to constitute a portion corresponding to the base board 1 as a multi-layer substrate which is made by sticking a plurality of base board layers via wiring layers therebetween.

Application of solder resist layer 4 onto the base board 1 can be done, for example, by using screen printing. In such case, the resist material can be applied by using a spraying method or by using a roller. It is also possible to apply the resist material on the screen onto the base board 1 by using a brush. By using these method, it is possible to appropriately fill the through holes 2 of the wiring substrate 20 with the resist material and to obtain the uniform solder resist layer 4. As shown in FIG. 1A, the solder resist material is applied to the area surrounded by the circumference 13 of the solder resist layer 4 by using the screen printing.

After applying the resist material onto the base board 1, the resist material is exposed and developed, and necessary opening portions such as the solder resist opening portions 4a for forming external terminals and the like are formed. As the necessary opening portions of the solder resist layer 4 other than the opening portions 4a and 4b, there are, for example, holes for positioning the metal mold for resin molding, opening portions for determining cutting locations in a package dicing process, and the like. The material of the solder resist layer 4 is not limited to photosensitive materials.

Also, the areas of the solder resist layer 4 on the backside of the wiring substrate 20 are separately formed every wiring substrate portions 20a. Therefore, when compared with the conventional structure in which the solder resist layer 104 is formed continuously through whole surface of the backside of the wiring substrate 130, it is possible to avoid a warp in the wiring substrate 20 caused by the difference of the heat contraction between the base board 1 and the solder resist layer 4.

An explanation will now be described on a method of manufacturing a semiconductor device according to an embodiment of the present invention which uses the package group molding and dicing method.

First, the wiring substrate 20 having the above-mentioned structure is prepared. On the face side surface of the wiring substrate 20, a semiconductor chip 7 is bonded on each of the wiring substrate module 20a via bonding material, that is, die bonding material. Thereafter, electrode pads of each of the semiconductor chip 7 and wire bonding portions 11 of the wiring substrate 20 are wire bonded to electrically couple therebetween via gold wires.

Then, a process of package group molding is performed. That is, the plurality of semiconductor chips bonded on the wiring substrate 20 and the gold bonding wires are molded or sealed within mold resin as a whole or group. When performing such resin molding, a metallic mold having a predetermined shape is disposed on the surface of the wiring substrate 20, and the space formed by the metallic mold and the wiring substrate 20 is filled with the mold resin. To perform the package group molding, the mold resin is filled continuously even on portions between the adjacent semiconductor chips.

Solder balls 5 for constituting external terminals are then bonded to the land portions 12 for bonding external terminals, which land portions are exposed via opening portions 4a of the solder resist layer 4. Thereby, a substrate assembly is obtained.

A package dicing process is then performed to obtain separate semiconductor devices. As an example, an explanation will be made on the case the substrate assembly is diced by using a dicing saw. The dicing saw, that is, a cutting blade, is made, for example, by adhering diamond abrasive onto the outer circumference of a metal disk. The cutting blade is rotated, and, by using the rotating cutting blade, the substrate assembly is cut along a grid shaped cutting area 14 located between the wiring substrate portions 20a shown by dotted lines 10 in FIG. 1A. In this case, the solder resist layer 4 does not exist on the cutting area 14 and on the area along both sides of the cutting area 14 of the backside of the wiring substrate 20. Therefore, the cutting blade does not contact the solder resist layer 4 on the backside of the wiring substrate 20. As a result, it is possible to avoid occurrence of defects such as cracks, chips and the like in the solder resist layer 4 caused by the contact of the cutting blade with the solder resist layer 4 and to safely perform package dicing.

The base board 1 and the mold resin 9 are cut by the cutting blade. Thereby, the wiring substrate 20 and the mold resin thereon of the substrate assembly is cut into separate pieces, and, as a result, separate semiconductor devices 21 as shown in FIGS. 2A and 2B are manufactured.

Next, an explanation will be made on a semiconductor device 21 as an embodiment of the present invention.

As shown in FIG. 2B, the semiconductor device 21 according to an embodiment of the present invention has a wiring substrate portion comprising a base board 1 having through holes 2, copper wiring conductors 3 formed on the face surface, on the back surface and on inner surfaces of the through holes 2 of the base board 1, and a solder resist layer 4 which insulates and coats the base board 1 and the copper wiring conductors 3 and which has predetermined opening portions. The semiconductor device 21 further comprises bonding material, that is, die bonding material, 6 applied onto the wiring substrate, a semiconductor chip 7 bonded onto the face surface of the wiring substrate via the bonding material 6, gold wires 8 coupling between electrode pads of the semiconductor chip 7 and wire bonding portions 11 of the copper wiring conductors 3, mold resin 9 sealing the face side surface of the wiring substrate on which the semiconductor chip 7 and the gold wires 8 are provided, and solder balls 5 joined at the opening portions of the solder resist layer 4 on the back side of the wiring substrate. The semiconductor device 21 is fabricated by using the package group molding and dicing method mentioned above.

The solder resist layer 4 functions to insulate between the wiring conductors, between the external terminals, between the wiring conductors and the semiconductor chip, and the like. As the bonding material, that is, the die bonding material 6, silver paste, resin, eutectic alloy and the like is used. As the mold resin 9, epoxy resin is mainly used. However, it is also possible to use another resin such as polyimide resin and the like.

As shown in FIG. 2A, when the backside of the semiconductor device 21 is observed, the outer circumference 13 of the solder resist layer 4 is located slightly inside the outer circumference 10a of the semiconductor device or semiconductor device package after dicing. It should be noted that the outer circumference 10a of the semiconductor device package corresponds to the location on the wiring substrate 20 shown by the dotted lines 10 of FIG. 1A. Therefore, at the peripheral portion on the backside of the semiconductor device 21, the solder resist layer 4 is not formed and the base board 1 is exposed. Also, as shown in FIG. 2B, the outer edge portion of the wiring substrate 20 formed of the base board 1, the copper wiring conductors 3 and the solder resist layer 4, and the edge portion of the mold resin 9 are located coplanar with each other in the side surface of the semiconductor device 21 which is the cut plane formed by the package dicing. However, it should be noted that the outer edge portion 13 of the solder resist layer 4 on the backside of the semiconductor device 21 is located slightly inside the side surface 10a of the semiconductor device 21 which is the cut plane formed by the package dicing.

The solder resist layer 4 on the backside of the wiring substrate 20 does not contact with the cutting blade and does not suffer stress from the cutting blade, in the package dicing process. Therefore, in the solder resist layer 4 of the semiconductor device 21, defects such as cracks, chips and the like are not caused by the package dicing process.

Also, the solder resist layer 4 on the face surface of the wiring substrate 20 is covered by the mold resin 9. Therefore, even when the solder resist layer 4 on the face surface of the wiring substrate 20 is cut in the package dicing process, stress is not applied to the solder resist layer 4 on the face side surface of the wiring substrate 20 and the crack and the like does not occur in the solder resist layer 4. However, in case the face side surface of the wiring substrate 20 is not covered by the mold resin and the like, it is preferable that the solder resist layer 4 is not formed in the area where the cutting blade contacts in the package dicing process even on the face side surface of the wiring substrate 20.

In the above-mentioned semiconductor device 21, internal connection is performed by using the wire bonding system. However, the present invention is not limited to using such wire bonding system, but it is possible to use other internal connection technology such as flip-chip connection, tape automated bonding (TAB) and the like.

Also, in the above-mentioned semiconductor device 21, external connection is performed by using the BGA system. However, the present invention is not limited to using such system, but it is possible to use other external connection technology such as land grid array (LGA) system in which each external terminal is formed as an island shaped terminal, pin grid array (PGA) system in which each external terminal is formed as a pin shaped terminal and the like.

Further, in the above-mentioned embodiment, a plurality of semiconductor chips bonded on the wiring substrate 20 and the gold bonding wires are molded or sealed within mold resin as a whole or group. However, it is possible to define a plurality of mold areas on a wiring substrate and to include in each mold area a plurality of wiring substrate portions 20a disposed regularly, as shown in FIG. 1A. In the above-mentioned package molding process, each of the mold areas is separately molded by the mold resin 9 such that a plurality of semiconductor chips and the gold bonding wires within each mold area are molded or sealed as a group. Thereafter, the package dicing process is performed for each mold area and the semiconductor devices are fabricated. It is intended that the package group molding and dicing method according to the present invention includes these both methods.

As mentioned above, in the present invention, the wiring substrate has a plurality of wiring substrate portions which are disposed regularly and each of which corresponds to a single semiconductor device. Each of the wiring substrate portions has a separate solder resist area having opening portions for forming external terminals, on the back side of the wiring substrate. On the backside of the wiring substrate, the solder resist is not formed on the location corresponding to the circumference portion of each semiconductor device package after dicing and on the area on both sides of the location. That is, the outer circumference of each solder resist area on the back side of the wiring substrate is located slightly inside the location corresponding to the outer circumference of each of the packages after dicing. The solder resist layer does not exist on the area of the backside of the wiring substrate where the cutting blade contacts during the dicing process.

Therefore, the cutting tool such as the cutting blade does not contact the solder resist layer during the package dicing process. The cutting blade does not cut the solder resist layer but cuts only the substrate portion. Thus, it is possible to avoid occurrence of defects such as cracks, chips and the like in the solder resist layer which insulates the wiring conductors on the backside of the wiring substrate and to safely perform package dicing.

As a result, it is possible to avoid occurrence of breaks and short circuits of wiring conductors caused by the defects of the solder resist layer.

Also, it is possible to avoid a warp in the wiring substrate, and it is further possible to improve a manufacturing yield of the semiconductor device and to reduce a manufacturing cost thereof.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative sense rather than a restrictive sense, and all such modifications are to be included within the scope of the present invention. Therefore, it is intended that this invention encompasses all of the variations and modifications as fall within the scope of the appended claims.

What is claimed is:

1. A semiconductor device comprising:
a wiring substrate portion having wiring conductors formed on at least a first surface thereof and having a solder resist layer which is formed on said first surface of said wiring substrate portion except on the peripheral portion on said first surface of the wiring substrate portion and which has opening portions for forming external terminals; and
at least one semiconductor chips bonded on a second surface of said wiring substrate portion, said second surface being an opposite surface to said first surface.

2. A semiconductor device as set forth in claim 1, wherein said semiconductor device further comprises a mold resin portion for sealing said at least one semiconductor chips on said wiring substrate portion.

3. A semiconductor device as set forth in claim 1, wherein in said peripheral portion on said first surface of said wiring substrate portion, an insulating base material layer of said wiring substrate portion is exposed.

4. A semiconductor device as set forth in claim 1, wherein, on said first surface of said wiring substrate, said wiring conductors are covered with said solder resist layer except portions which are exposed via said opening portions for forming external terminals.

5. A semiconductor device as set forth in claim 1, wherein said semiconductor chip is electrically coupled with wiring conductors formed on said second surface of said wiring substrate.

6. A semiconductor device as set forth in claim 1, wherein said semiconductor device further comprises said external terminals formed on portions of said first surface of said wiring substrate which are exposed via said opening portions for forming external terminals.

7. A semiconductor device as set forth in claim 1, wherein a solder resist layer is also formed on said second surface of said wiring substrate portion.

8. A semiconductor device as set forth in claim 7, wherein said solder resist layer is not formed on a peripheral portion on said second surface of said wiring substrate.

9. A semiconductor device as set forth in claim 1, wherein said semiconductor device is manufactured by using a package group molding and dicing method.

10. A wiring substrate used for manufacturing a semiconductor device, said wiring substrate comprising:
wiring conductors formed on at least a first surface of said wiring substrate;
a plurality of wiring substrate portions which are located regularly and each of which corresponds to a single semiconductor device to be manufactured; and
a plurality of solder resist layer portions which are formed on said first surface of respective wiring substrate portions and each of which has opening portions for forming external terminals, an outer circumference of each of said solder resist layer portions being located inside a corresponding one of said wiring substrate portions.

11. A wiring substrate as set forth in claim 10, wherein, in a peripheral portion of each of said wiring substrate portions and an area between said wiring substrate portions on said first surface of said wiring substrate, said resist layer is not formed and an insulating base material layer of said wiring substrate is exposed.

12. A wiring substrate as set forth in claim 10, wherein, on said first surface of said wiring substrate, said wiring conductors are covered with said solder resist layer except portions which are exposed via said opening portions for forming external terminals.

13. A wiring substrate as set forth in claim 10, wherein said wiring substrate is used for manufacturing said semiconductor device by using a package group molding and dicing method.

14. A wiring substrate as set forth in claim 10, wherein said semiconductor device is manufactured by mounting at least one semiconductor chips on a second surface of each of said wiring substrate portions opposite to said first surface and by dicing said wiring substrate into said wiring substrate portions.

15. A method of manufacturing a semiconductor device comprising:
preparing a wiring substrate having wiring conductors formed on at least a first surface of said wiring substrate, said wiring substrate having: a plurality of wiring substrate portions which are located regularly and each of which corresponds to a single semiconductor device to be manufactured; and a plurality of solder resist layer portions which are formed on said first surface of respective wiring substrate portions and each of which has opening portions for forming external terminals, an outer circumference of each of said solder resist layer portions being located inside a corresponding one of said wiring substrate portions;
mounting at least one semiconductor chips on a second surface of each of said wiring substrate portions opposite to said first surface; and
dicing said wiring substrate into said semiconductor devices each comprising a wiring substrate portion, said wiring substrate being cut by a cutting tool along an outer circumference of said wiring substrate portion, and said cutting tool does not contact said solder resist layer portions on said first surface of said wiring substrate.

16. A method of manufacturing a semiconductor device as set forth in claim 15, wherein, in a peripheral portion of each of said wiring substrate portions and an area between said wiring substrate portions on said first surface of said wiring substrate, said resist layer is not formed and an insulator base board layer of said wiring substrate is exposed.

17. A method of manufacturing a semiconductor device as set forth in claim 16 wherein, on said first surface of said wiring substrate, said wiring conductors are covered with said solder resist layer except portions which are exposed via said opening portions for forming external terminals.

18. A method of manufacturing a semiconductor device as set forth in claim 15, further comprising:
after mounting at least one semiconductor chips on said second surface of each of said wiring substrate portions, sealing said semiconductor chips mounted on said second surface of said wiring substrate by using mold resin; and
wherein, in said dicing said wiring substrate into said semiconductor devices, said cutting tool cuts said wiring substrate and said mold resin on the second surface of said wiring substrate along the outer circumference of said wiring substrate portions without contacting said solder resist layer on said first surface of said wiring substrate.

19. A method of manufacturing a semiconductor device as set forth in claim 15, wherein, in said mounting at least one semiconductor chips on said second surface of each of said wiring substrate portions, said at least one semiconductor chips are electrically coupled with wiring conductors formed on said second surface of corresponding one of said wiring substrate portions.

20. A method of manufacturing a semiconductor device as set forth in claim 15, wherein said preparing said wiring substrate comprises:
preparing a base material layer made of an insulating material;
forming wiring conductors in predetermined areas on at least a first surface of said base material layer, and forming a plurality of wiring substrate portions which are located regularly and each of which corresponds to a single semiconductor device to be manufactured; and
forming a plurality of solder resist layer portions which are formed on said first surface of respective wiring substrate portions and each of which has opening portions for forming external terminals, an outer circumference of each of said solder resist layer portions being located inside a corresponding one of said wiring substrate portions and, on said first surface of said wiring substrate, said wiring conductors are covered with said solder resist layer except portions which are exposed via said opening portions for forming external terminals.
